(19) United States
(12) Patent Application Publication
(10) Pub. No.: US 2013/0084531 A1
(43) Pub. Date: Apr. 4, 2013

(54) METHOD OF PRODUCING ORGANIC ELECTROLUMINESCENCE DISPLAY DEVICE

(71) Applicant: CANON KABUSHIKI KAISHA, Tokyo (JP)

(72) Inventors: Atsushi Hamaguchi, Yokohama-shi (JP); Nobuhiko Sato, Mobara-shi (JP)

(73) Assignee: CANON KABUSHIKI KAISHA, Tokyo (JP)

(21) Appl. No.: 13/623,919

(22) Filed: Sep. 21, 2012

(30) Foreign Application Priority Data
Sep. 30, 2011 (JP) 2011-217663
Aug. 30, 2012 (JP) 2012-189766

(51) Int. Cl. G03F 7/20

(52) U.S. Cl. 430/319

(57) ABSTRACT

Provided is a method of producing an organic electroluminescence display device including patterning by photolithography, the method including: forming an organic compound layer containing a low-molecular organic electroluminescence material and an intermediate layer for protecting the organic compound layer; forming a resist layer on the intermediate layer; irradiating the resist layer with ultraviolet light through a photomask to partially remove the resist layer in a region irradiated with the ultraviolet light; and removing the organic compound layer in a region from which the resist layer is removed, in which the resist layer includes a layer formed of a positive resist, and the intermediate layer includes a layer formed of a high-molecular organic material having a chain structure, capable of being selectively dissolved in a solvent that dissolves the organic compound layer.

### BACKGROUND OF THE INVENTION

1. Field of the Invention

The present invention relates to a method of producing an organic electroluminescence (EL) display device.

2. Description of the Related Art

An organic EL display device is a display device (display) in which multiple organic EL elements are arranged in matrix. The organic EL display device is drawing attention as a potential candidate for a flat panel display because the device has high contrast and can be easily reduced in thickness. Further, the organic EL display device has a remarkably high response speed compared with liquid crystal, and hence, is considered to be suitable for displaying a moving image.

A display region of the organic EL display device is divided two-dimensionally with high definition, for example, by sub-pixels including any one of organic EL elements of three colors (red, green, blue). A desired full-color image can be obtained by regulating an emission amount of each sub-pixel.

As a method of producing a high-definition organic EL display device, various methods have been proposed. One of those methods is one using photolithography. For example, Japanese Patent No. 3839276 discloses a method of forming a layer serving as a common electrode after repeating the step of patterning an organic compound layer formed on the entire surface of a substrate by photolithography to allow the organic compound layer to remain only in a predetermined site for three colors. Further, Japanese Patent No. 4507759 discloses a method including the step of forming an intermediate layer formed of alcohol-soluble nylon containing a light-absorbing material and a resist material layer on an organic material layer and the step of patterning the intermediate layer and the resist material layer.

However, as a result of extensive studies made by the inventors of the present invention, it has been clarified that the following problem arises when an organic compound layer constituting an organic EL element is patterned by photolithography.

Specifically, there is a problem in that light emitted from an exposure light source used in photolithography contains light in an ultraviolet region, which may degrade a constituent material for an organic EL element. Bond energy of a carbon-carbon bond contained in an organic compound that is a constituent material for a general organic EL element is about 3 eV (wavelength: 413 nm). Therefore, when light emitted from a light source used in photolithography contains ultraviolet light, the constituent material for the organic EL element is exposed to the ultraviolet light. As a result, a bond such as a carbon-carbon bond of the organic compound that is the constituent material for the organic EL element is cleaved, and consequently, light emitting efficiency and emission lifetime of the organic EL element may decrease.

Further, the method disclosed in Japanese Patent No. 4507759, that is, the method of providing an intermediate layer containing a light-absorbing material on a constituent material for an organic EL element has a problem in that ultraviolet light is not shielded sufficiently unless a thickness of the intermediate layer is sufficiently large. Further, the method disclosed in Japanese Patent No. 4507759 has a problem in that a light-absorbing material to be used may remain as a residue during removal of an intermediate layer, and the residue degrades emission characteristics of an organic EL element.

### SUMMARY OF THE INVENTION

The present invention has been achieved in view of the above-mentioned problems, and an object of the present invention is to provide a method of producing an organic EL display device for producing an organic EL display device with high efficiency, long lifetime, and high definition at low cost.

A method of producing an organic EL display device of the present invention is a method of producing an organic EL display device including patterning an organic compound layer by photolithography, the method comprising; forming an organic compound layer comprising a low-molecular organic electroluminescence material, forming an intermediate layer for protecting the organic compound layer on the organic compound layer, forming a resist layer on the intermediate layer, irradiating the photoresist layer with ultraviolet light through a photomask having a patterned light shielding portion to partially remove the resist layer in a region irradiated with the ultraviolet light; and removing the organic compound layer in a region from which the resist layer is removed, wherein the resist layer comprises a layer formed of a positive resist, and the intermediate layer comprises a layer formed of a high-molecular organic material having a chain structure, capable of being selectively dissolved in a solvent that dissolves the organic compound layer.

According to the present invention, it is possible to provide a method of producing an organic EL display device for producing an organic EL display device with high efficiency, long lifetime, and high definition at low cost.

According to the production method of the present invention, when an organic compound layer is processed by photolithography, a positive resist is provided in a region where the organic compound layer to be processed is to remain, and the positive resist shields light from an exposure light source together with (a light shielding portion of) a photomask.

Therefore, the remaining organic compound layer is not irradiated with ultraviolet light to which a photoresist is exposed, used in an exposing step, and hence, an organic EL element included in a device is not damaged. On the other hand, a high-molecular material that can be selectively dissolved is not easily etched, compared with a low-molecular organic EL material, due to its structure, and a residue thereof is liable to remain.

Typical examples of the high-molecular material include polyvinylpyrrolidone (PVP) and polyvinyl alcohol (PVA). Unlike a resin to be configured by cross-linking after coating, those high-molecular materials are chain high molecules having no three-dimensionally bonded network structure in order to ensure solubility, and are etched non-uniformly, with the result that a residue thereof is liable to remain in some cases.

According to the present invention, a portion to be etched can be irradiated with ultraviolet light as used in exposure with a patterning mask interposed, and hence, a high-molecular material can be decomposed in advance before dry etching, which can reduce a residue. The amount of a residue after the removal of an intermediate layer, which decreases emission characteristics of an organic EL element, decreases, and thus, satisfactory emission characteristics of the organic EL element can be obtained.

Further features of the present invention will become apparent from the following description of exemplary embodiments with reference to the attached drawings.

### BRIEF DESCRIPTION OF THE DRAWINGS

FIG. 1 is a schematic cross-sectional view illustrating an example of an organic EL display device produced by a production method of the present invention.

FIGS. 2A, 2B, 2C, 2D, 2E, 2F, 2G, 2H, and 2I are schematic cross-sectional views illustrating an example of a method of producing an organic EL display device according to an embodiment of the present invention.

FIGS. 3A, 3B, 3C, 3D, and 3E are views illustrating steps of FIGS. 2B, 2C, and 2D in detail.

FIG. 4 is a partially enlarged view of FIG. 3B.

FIG. 5 is a graph showing measurement and evaluation results of light emitting efficiency of a green sub-pixel included in an organic EL display device produced in Example 1.

FIG. 6 is a graph showing measurement and evaluation results of light emitting efficiency of a green sub-pixel included in an organic EL display device produced in Comparative Example 1.

FIGS. 7A, 7B, 7C, and 7D are schematic cross-sectional views illustrating the step of processing an organic compound layer in Comparative Example 1.

### DESCRIPTION OF THE EMBODIMENTS

A production method of the present invention is a method of producing an organic EL display device including a patterning step using photolithography.

In the present invention, a resist used in photolithography is a positive resist. Further, in the present invention, a total of a light transmittance of a light shielding portion of a photomask used in photolithography and a light transmittance of the positive resist may be 1% or less with respect to light from an exposure light source. It should be noted that a positive resist to be evaluated for a light transmittance refers to a positive photoresist that remains on a patterned layer even after a patterning step using photolithography.

Hereinafter, the present invention is described in detail with reference to the drawings, if required. It should be noted that a method of producing an organic EL display device described below is, as a specific example of the present invention, a method of producing a top-emission type display device by using both vacuum deposition and photolithography, in which a constituent material for an organic EL element included in an organic EL display device is a low-molecular organic compound.

In the present invention, a low-molecular organic material means an organic compound having a molecular weight of several hundreds or less. The low-molecular organic material is generally a solid at a room temperature and is capable of being formed into a film by vacuum deposition. Doping may be performed in the low-molecular organic material. Doping material includes an alkali metal, an alkali earth metal and compounds thereof. Further, a metal complex may be used for the doping material. However, the present invention is not limited to this specific example. The present invention can also be applied to the production of a bottom-emission type organic EL display device.

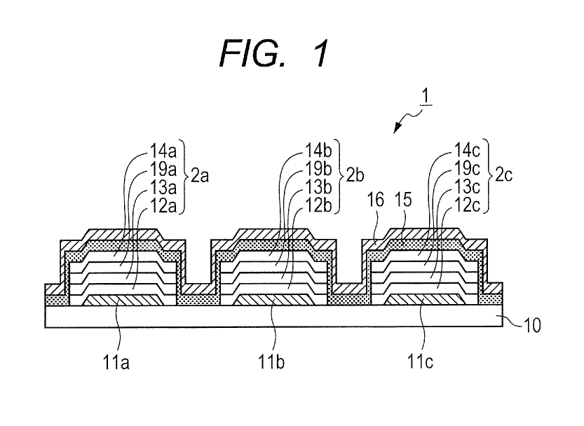

FIG. 1 is a schematic cross-sectional view illustrating an example of an organic EL display device produced by the production method of the present invention. It should be noted that FIG. 1 illustrates a part of an organic EL display device to be produced actually. An organic EL display device 1 of FIG. 1 includes three kinds of organic EL elements, that is, a first organic EL element, a second organic EL element, and a third organic EL element. Further, the first organic EL element is a constituent member of a first sub-pixel, the second organic EL element is a constituent member of a second sub-pixel, and the third organic EL element is a constituent member of a third sub-pixel. In addition, a set of the three kinds of organic EL elements illustrated in FIG. 1 functions as a minimum unit of color information constituting an image, and the set of the organic EL elements are arranged two-dimensionally, whereby an organic EL display device is configured. It should be noted that the three kinds of organic EL elements illustrated in FIG. 1 are each any one of a blue organic EL element, a green organic EL element, and a red organic EL element, and emission color of each organic EL element can be determined freely.

In this case, in the first organic EL element, a lower electrode 11a, a hole transport layer 12a, an emission layer 13a, a hole blocking layer 19a, an electron transport layer 14a, an electron injection layer 15, and an upper electrode 16 are provided in this order on a substrate 10. It should be noted that, in the following description, a laminate formed of the layers (12a, 13a, 14a, and the like) other than the electrodes (lower electrode 11a, upper electrode 16) and the electron injection layer 15 included in the first organic EL element is sometimes referred to as first organic compound layer 2a.

Further, in the second organic EL element, a lower electrode 11b, a hole transport layer 12b, an emission layer 13b, an electron transport layer 14b, an electron injection layer 15, and an upper electrode 16 are provided in this order on the substrate 10. It should be noted that, in the following description, a laminate formed of the layers (12b, 13b, 14b, and the like) other than the electrodes (lower electrode 11b, upper electrode 16) and the electron injection layer 15 included in the second organic EL element is sometimes referred to as second organic compound layer 2b.

Further, in the third organic EL element, a lower electrode 11c, a hole transport layer 12c, an emission layer 13c, an electron transport layer 14c, an electron injection layer 15, and an upper electrode 16 are provided in this order on the substrate 10. It should be noted that, in the following description, a laminate formed of the layers (12c, 13c, 14c, and the like) other than the electrodes (lower electrode 11c, upper electrode 16) and the electron injection layer 15 included in the third organic EL element is sometimes referred to as third organic compound layer 2c.

It should be noted that the layer configuration of the organic compound layers (2a, 2b, 2c) is not particularly limited, as long as the organic compound layers (2a, 2b, 2c) respectively include the emission layers (13a, 13b, 13c). In this case, layers that may be included in the organic compound layers (2a, 2b, 2c) are, for example, a hole injection layer, a hole transport layer, an electron transport layer, a hole blocking layer, and an electron blocking layer, in addition to the emission layer.

Further, although not shown in FIG. 1, the lower electrodes 11a, 11b, and 11c may be connected to thin film transistors (TFTs). A planarized passivation film may be provided on the substrate 10. In particular, when the substrate 10 includes TFTs, it is preferred that a planarized passivation film be provided so as to fill irregularities generated by the TFTs.

In the organic EL display device produced by the production method of the present invention, a known organic compound may be used as a constituent material for the organic compound layer included in the organic EL display device. Of those, an organic material having absorption with respect to a wavelength of a light source of an exposure device is used preferably. Further, the organic compound layer preferably contains, as the constituent material for the layer, an organic compound including at least one skeleton of an anthracene skeleton, a chrysene skeleton, a fluorene skeleton, a fluoranthene skeleton, a phenanthroline skeleton, a carbazole skeleton, a triphenylene skeleton, a triphenylamine skeleton, an azatriphenylene skeleton, and an arylamine skeleton.

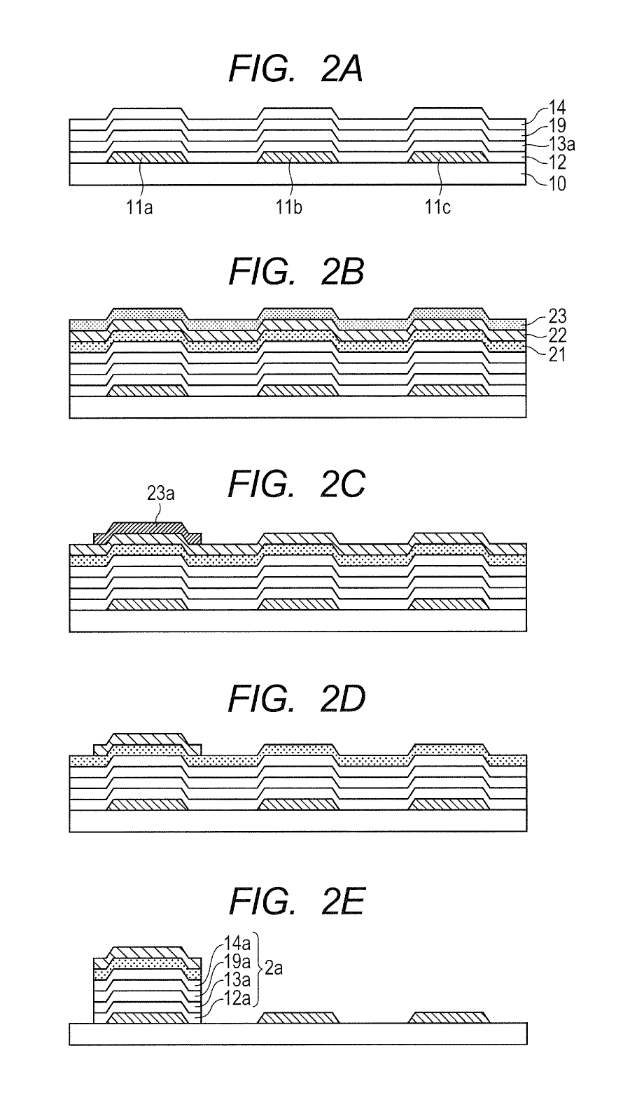

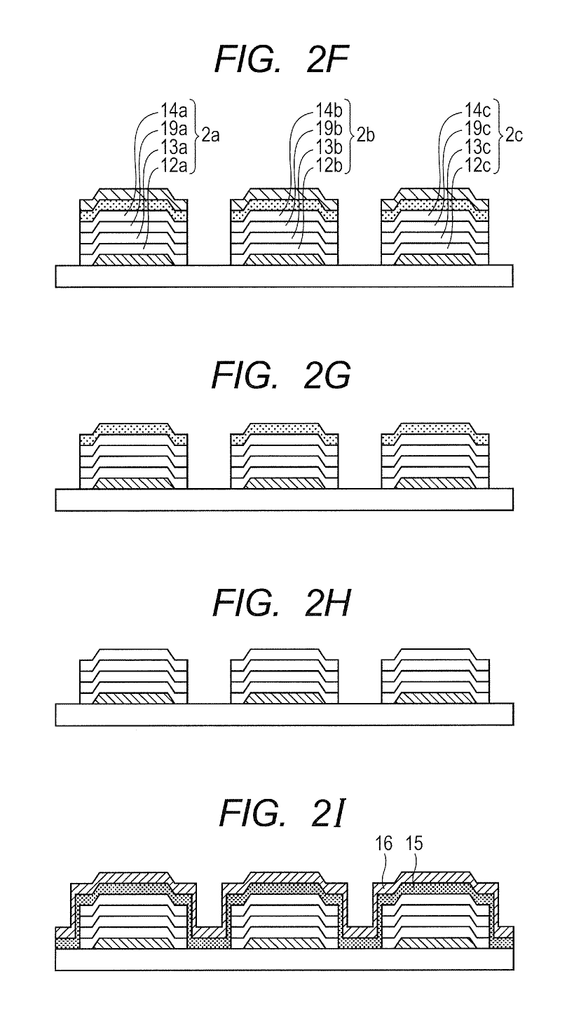

Next, a method of producing an organic EL display device of the present invention is described. FIGS. 2A to 2I are schematic cross-sectional views illustrating an example of a method of producing an organic EL display device according to an embodiment of the present invention. It should be noted that a process illustrated in FIGS. 2A to 2I corresponds to a production process for the organic EL display device 1 of FIG. 1.

(Substrate with Lower Electrodes)

First, a substrate 10 with lower electrodes (11a, 11b, 11c) formed thereon is prepared. In this case, in the production of a top-emission type organic EL device, it is desired that the lower electrodes have a high reflectance with respect to visible light.

(Step of Forming First Organic Compound Layer)

Next, in order to form a first sub-pixel to serve as a sub-pixel of a first color, layers constituting a first organic compound layer 2a are laminated successively on the substrate 10 (FIG. 2A). It should be noted that, in FIG. 2A, a hole transport layer 12, a first emission layer 13a, a hole blocking layer 19, and an electron transport layer 14 are formed in this order. However, in the present invention, layers to be formed as the first organic compound layer 2a are not limited thereto. Further, as a method of forming the layers constituting the first organic compound layer 2a, a coating method by spin coating, vacuum deposition, dipping, or the like is conceivable. However, the method is not particularly limited. It should be noted that, when the organic compound layer is formed through use of vacuum deposition, a mask for covering a substrate end may be used. In this regard, however, in this case, a high-precision mask is not required, considering that patterning is performed by photolithography in a later step.

(Step of Forming Intermediate Layer)

Next, intermediate layers (21, 22) for protecting the first organic compound layer 2a formed previously from a resist, a developing solution, oxygen, water, and the like are provided (FIG. 2B). It should be noted that, in FIG. 2B, the intermediate layer has a two-layered configuration, and specifically, the first intermediate layer 21 and the second intermediate layer 22 are laminated in this order from the first organic compound layer 2a side.

In this case, a constituent material for the first intermediate layer 21 is a high-molecular organic material that can be dissolved selectively in a solvent that does not dissolve the organic compound layer. Examples of the high-molecular organic material include water-soluble polymer materials such as polyvinylpyrrolidone (PVP), polyvinyl alcohol (PVA), polyvinyl caprolactam (PVCAP), polyethylene glycol (PEG), and a vinylpyrrolidone copolymer. In this regard, however, in the present invention, the high-molecular organic material is not limited thereto, and nylon or the like that is an alcohol-soluble polymer material may also be used. An example of the alcohol-soluble polymer material is CM4000 (produced by Toray Industries, Inc.).

Further, examples of the constituent material for the second intermediate layer 22 include silicon nitride, amorphous silicon, and silicon oxide. In the present invention, the constituent material is not limited thereto.

(Step of Processing Intermediate Layer)

Next, the intermediate layers (21, 22) are processed so as to remain only on the first sub-pixel that is a sub-pixel of a first color by patterning through use of photolithography (FIGS. 2B to 2D). In this case, the intermediate layers (21, 22) are processed, for example, in the following steps (i) to (iv).

(i) Step of forming a resist layer (FIG. 2B)
(ii) Exposing step
(iii) Developing step (FIG. 2C)
(iv) Step of etching intermediate layers (FIG. 2D)

Hereinafter, the step of processing the intermediate layers is described in detail.

First, a photoresist is applied onto the second intermediate layer 22 through use of a spin coater or the like to form a resist layer 23 (FIG. 2B). It should be noted that, prior to the application of the photoresist, hexamethyldisilazane (HMDS) or the like may be used as a promoter for adhesion. Further, after the application of the photoresist, baking is performed, if required.

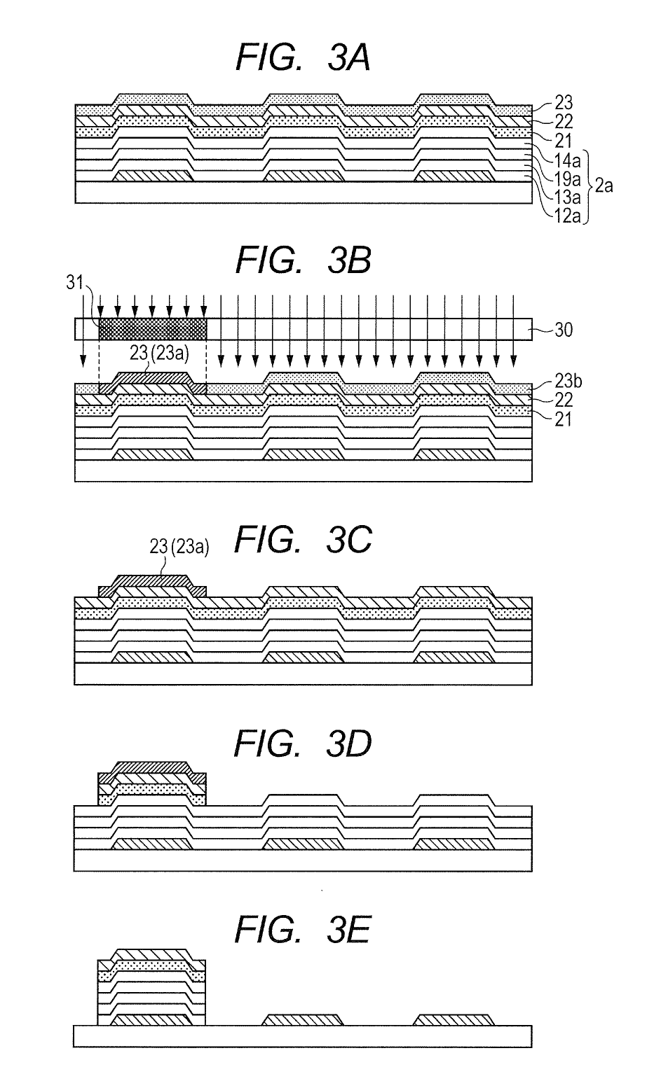

FIGS. 3A to 3E are schematic cross-sectional views illustrating the step of forming a resist layer to the step of processing an organic compound layer. It should be noted that FIGS. 3A to 3E illustrate the steps of FIGS. 2B to 2D in detail. As illustrated in FIG. 3A, the resist layer 23 is formed. After that, as illustrated in FIG. 3B, when the exposing step is performed, the exposure is performed with a photomask 30 having a desired shape placed above the resist layer 23 or the photomask 30 placed in close contact with the resist layer 23, and a pattern formed on the photomask is transferred to the resist layer (exposing step). In this case, the photoresist to be used in the present invention is a positive photoresist. Therefore, in the developing step performed after the exposing step, a region 23a of the resist layer 23, which is not exposed to light, remains even after the developing step, whereas a region 23b exposed to light is removed from the second intermediate layer 22 in the developing step (FIG. 3C).

In the exposing step, depending on the material for a positive resist, an exposure light source is used. For example, a g-line (435 nm), an h-line (405 nm), an i-line (365 nm), krypton fluoride (KrF: 248 nm), or argon fluoride (ArF: 193 nm) may be used. Of the exposure light sources, a g-line (436 nm) is preferably used. Note that, as described above, when the wavelength of an exposure light source contains light of about 3 eV (wavelength: 413 nm) or less, which is bond energy of a carbon-carbon bond generally included in an organic compound, the bond such as a carbon-carbon bond is cleaved and the light emitting efficiency and emission lifetime of the organic EL element may be degraded. Thus, in the present invention, a total of a light transmittance of a light shielding portion 31 of the photomask 30 with respect to the wavelength of a light source of an exposure device and a light transmittance of the resist layer 23 (positive photoresist) is set to 1% or less. Thus, by minimizing the total of the light transmittances of the light shielding portion 31 of the photomask 30 and the resist layer 23 through use of the positive resist as a constituent material for the resist layer 23, a predetermined organic compound layer (first organic compound layer 2a) can be protected from light to be used in the exposing step. That is, during the exposing step, light that may strike the upper surface of a predetermined organic compound layer (first organic compound layer 2a) can be shielded by the light shielding portion 31 of the photomask 30 and the resist layer 23.

In this regard, however, in the exposing step, light emitted from the exposure light source may reach a region covered with the light shielding portion 31 of the photomask and the resist layer 23 from a side surface direction owing to, for example, the diffraction and reflection of light. Therefore, it is necessary to shield light emitted from the exposure light source as much as possible so as to prevent the light from reaching a predetermined organic compound layer (first organic compound layer 2a) from the side surface direction.

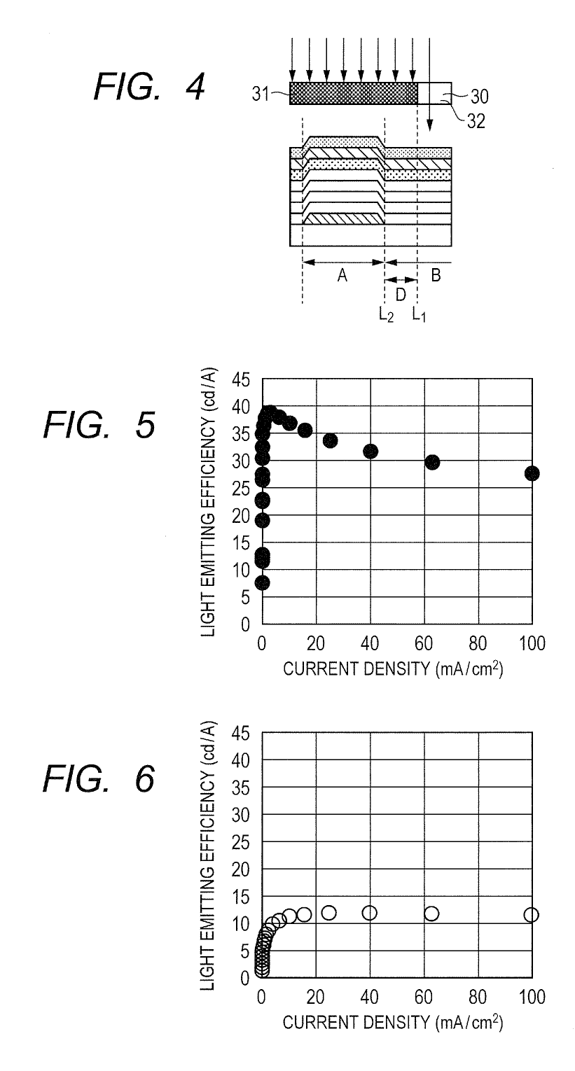

FIG. 4 is a partially enlarged view of FIG. 3B. Specifically, FIG. 4 illustrates a light shielding region and a region on the periphery thereof in an enlarged state. In the present invention, as illustrated in FIG. 4, it is preferred to set a distance D in a planar direction between a border L₁ of the light shielding portion 31 and a non-light-shielding portion 32 of the photomask 30 and a border L₂ of an emission region A and a non-emission region B to be sufficiently large. In addition, it is more preferred to set the distance D to be a half or more of a resolution in photolithography.

Further, it is also effective to decrease transmission light in a horizontal direction by decreasing the light transmittance of a member provided between lower electrodes of adjacent sub-pixels. In the present invention, the light transmittance of the member provided between the lower electrodes of the adjacent two sub-pixels is preferably 85% or less, more preferably 15% or less, with respect to light having a wavelength emitted from the exposure light source. For example, it is conceivable to form a pixel separation layer made of polyimide or silicon nitride between the lower electrodes of the adjacent two sub-pixels to control the light transmittance with respect to light emitted from the exposure light source to be 85% or less.

On the other hand, in the present invention, it is preferred that the light transmittance of a transparent electrode that is an electrode on a side where light output from each organic EL element is extracted be 90% or less with respect to light of the exposure light source.

On the other hand, in the case where the substrate 10 constituting the organic EL display device includes a planarized passivation film, it is preferred that the light transmittance of the planarized passivation film be 1% or less with respect to light of the exposure light source.

The photomask 30 to be used in the exposing step has a light shielding region for preventing light such as ultraviolet light from being applied to the organic compound layer provided in a predetermined region, and in the light shielding region, for example, a metal thin film of Cr as a light shielding material is provided on a transparent glass substrate made of quartz. It should be noted that, the light shielding material included in the photomask 30 is not particularly limited as long as the light shielding material satisfies the features of the present invention.

Accordingly, in the present invention, when the organic compound layer is processed so as to remain in a predetermined region in the step of processing the organic compound layer, light emitted from the exposure device does not strike the organic compound layer provided in the predetermined region. Therefore, the organic compound layer provided in the predetermined region can be prevented from changing in characteristics due to light emitted from the exposure device.

After the exposing step is performed, development and baking are performed (developing step, FIGS. 2C and 3C). It should be noted that, at a time when the developing step is performed, the resist layer remains only on the sub-pixel of a first color (first sub-pixel).

After the developing step is performed, an etching step is performed in which the patterned resist is subjected to dry etching to remove the intermediate layers (21, 22) provided on the sub-pixels other than the sub-pixel of a first color (second sub-pixel, third sub-pixel) (FIGS. 2D and 3D). When the etching step is performed, a known dry etching method may be adopted. In the case where the second intermediate layer 22 is made of silicon nitride, it is preferred to perform dry etching through use of carbon tetrafluoride gas (CF₄ gas). As illustrated in FIGS. 2D and 3D, this etching enables the intermediate layer formed of two layers (first intermediate layer 21, second intermediate layer 22) to remain only on the sub-pixel of a first color (blue sub-pixel). It should be noted that, although the resist layer 23a may be allowed to remain during the step of processing the intermediate layer, as illustrated in FIGS. 2D and 3D, the resist layer 23a may be removed during the step of processing the intermediate layer.

(Step of Processing First Organic Compound Layer)

Next, dry etching is performed through use the patterned intermediate layers (21, 22) as a mask to remove the first organic compound layer 2a provided on the sub-pixels (second sub-pixel, third sub-pixel) other than the sub-pixel of a first color (FIGS. 2E and 3E). When the step of processing the first organic compound layer 2a is performed, a known dry etching method may be adopted, and etching using oxygen as etching gas is preferred.

At this time, the intermediate layers on the sub-pixels (second sub-pixel, third sub-pixel) other than the sub-pixel of a first color are irradiated with light from the exposure light source, and hence, the intermediate layers are easily decomposed with ultraviolet light and do not easily remain as a residue.

A detailed description is made below. A high-molecular material that can be selectively dissolved in a solvent that does not dissolve an organic compound layer, which is used for the intermediate layers, is not etched easily owing to a structure thereof, compared with a low-molecular organic EL material, and easily remains as a residue. Examples of the high-molecular material include polyvinylpyrrolidone (PVP) and polyvinyl alcohol (PVA). Unlike a resin to be configured by cross-linking after coating, those high-molecular materials are chain high molecules having no three-dimensionally bonded network structure in order to ensure solubility, and are etched non-uniformly, with the result that a residue thereof is liable to remain in some cases. A portion to be etched can be irradiated with ultraviolet light as used in exposure with a patterning mask interposed, and hence, a high-molecular material can be decomposed in advance before dry etching, which can reduce a residue.

Through the above-mentioned process, the first organic compound layer 2a is provided selectively on the sub-pixel of a first color, that is, the first sub-pixel. It should be noted that, on the sub-pixel of a second color (second sub-pixel) and the sub-pixel of a third color (third sub-pixel), the organic compound layers (2b, 2c) and the intermediate layers (21, 22) are formed successively by the same method as that of the sub-pixel of a first color and patterned by photolithography. Thus, the desired organic compound layers (2b, 2c) are formed respectively on the sub-pixel of a second color (second sub-pixel) and the sub-pixel of a third color (second sub-pixel).

Accordingly, the organic compound layers (2a, 2b, 2c) of three colors are selectively formed in predetermined regions (FIG. 2F). It should be noted that, the order of forming the organic compound layers is not limited in the present invention.

When the patterning of the organic compound layers described above is performed by photolithography, the organic compound layers can be patterned with a resolution in the case of using a general mask exposure device, i.e., high definition that is a resolution of tens of μm or less. Therefore, compared with a method of forming a pattern through use of a high-definition metal mask used conventionally, an organic EL display device with higher definition can be produced.

(Step of Removing Intermediate Layer)

Immediately after completing the step of processing the organic compound layers, the intermediate layer including the first intermediate layer 21 and the second intermediate layer 22 remains on the respective organic compound layers (2a, 2b, 2c). Therefore, as the subsequent step, the step of removing the intermediate layer is performed (FIGS. 2G and 2H). For example, in the case where the first intermediate layer 21 is formed of polyvinylpyrrolidone (PVP), the PVP is water-soluble, and hence, if the first intermediate layer 21 is treated with water, the first intermediate layer 21 is dissolved in water and removed from the surfaces of the organic compound layers (2a, 2b, 2c). By using this, the second intermediate layer 22 formed on the first intermediate layer 21 can also be removed at a time. It should be noted that, in the case of removing the intermediate layers (21, 22) through use of a solvent such as water, it is necessary to remove the solvent adhering to the front surface or side surface of the organic compound layers (2a, 2b, 2c) by heating or the like after the treatment with the solvent.

It should be noted that, in the present invention, a constituent material for the first intermediate layer 21 is not limited to the above-mentioned PVP. For example, polyvinyl alcohol (PVA), which is a similarly water-soluble polymer material, or nylon, which is a polymer material soluble in alcohol may be used.

Further, a method of removing the intermediate layers is not limited to the method using a solvent, and the second intermediate layer 22 and the first intermediate layer 21 may be subjected to dry etching in the stated order to remove each intermediate layer (FIGS. 2F to 2H).

(Step of Forming Common Layer and Common Electrode)

Next, a layer common to the respective sub-pixels (common layer) and an electrode common to the respective sub-pixels (common electrode) are formed (FIG. 2I). Hereinafter, a specific example of the step of forming a common layer and a common electrode is described.

First, an electron injection layer 15 is formed on the organic compound layers (2a, 2b, 2c). A constituent material for the electron injection layer 15 is exemplified by an alkali metal, an alkali earth metal, and a compound of an alkali metal or an alkali earth metal. Further, the electron injection layer 15 is formed by vacuum deposition or the like.

Next, an upper electrode 16 that is a common electrode is formed. As a constituent material for the upper electrode 16, a known conductive material may be used, and it is preferred to use a metal having a small work function. Further, an optical adjustment layer such as an optical interference layer (not shown) may be provided on the upper electrode 16.

(Sealing Step)

After forming the electron injection layer 15 and the upper electrode 16, a sealing step is performed in which a sealing member for protecting an emission region having pixels and organic EL elements provided therein from water and the like is provided in a vacuum atmosphere or an atmosphere with the water amount limited.

The method described above may be applied to the organic EL display device 1 including the layer common to all the sub-pixels (common layer) and the electrode common to all the sub-pixels (common electrode). It should be noted that, the production method of the present invention is not limited to the method described above. For example, the production method of the present invention may also be applied to an embodiment in which the step of patterning using photolithography is repeated after the formation of the upper electrode.

Hereinafter, the present invention is described in more detail by way of examples. It should be noted that, the present invention is not limited to the examples described below.

### Example 1

The organic EL display device illustrated in FIG. 1 was produced by the following method.

(Step of Forming First Organic Compound Layer (Green Organic Compound Layer))

First, an organic material represented by the following formula was formed into a film as a hole transport layer 12 on a substrate 10 having lower electrodes (11a, 11b, 11c) of a size of 24.5 μm×70.0 μm provided thereon, patterned by photolithography after being formed by vacuum deposition. In this case, the thickness of the hole transport layer 12 was set to be 150 nm.

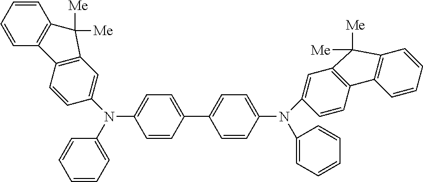 [SMILES: CC1(C)c2ccccc2-c2ccc(N(c3ccccc3)c3ccc(-c4ccc(N(c5ccccc5)c5ccc6c(c5)C(C)(C)c5ccccc5-6)cc4)cc3)cc21]

Next, a green emission layer to be a first emission layer 13a was formed on the hole transport layer 12 through vacuum deposition by co-depositing three kinds of materials represented by the following formulae. In this case, the thickness of the green emission layer was 20 nm.

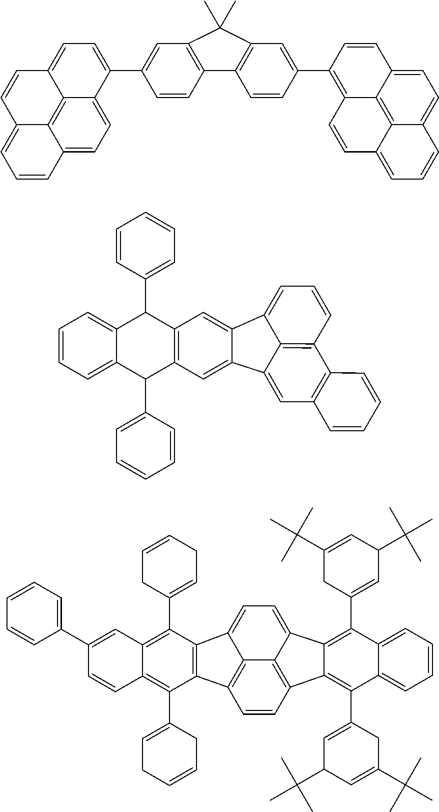

Next, an organic material represented by the following formula was formed into a film as a hole blocking layer 19 on the first emission layer 13a (green emission layer) by vacuum deposition. In this case, the thickness of the hole blocking layer 19 was set to be 10 nm.

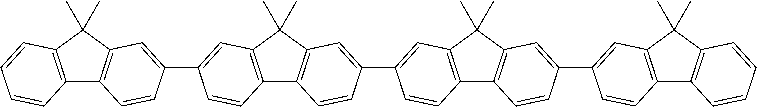 [SMILES: CC1(C)c2ccccc2-c2ccc(-c3ccc4c(c3)C(C)(C)c3cc(-c5ccc6c(c5)C(C)(C)c5cc(-c7ccc8c(c7)C(C)(C)c7ccccc7-8)ccc5-6)ccc3-4)cc21]

Next, an organic material represented by the following formula was formed into a film as an electron transport layer 14 on the hole blocking layer 19 by vacuum deposition. In this case, the thickness of the electron transport layer 14 was set to be 10 nm.

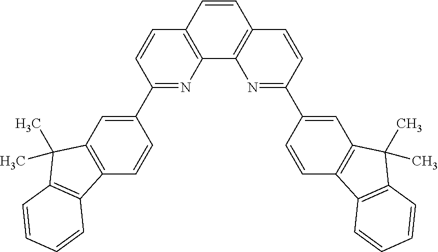

Thus, a first organic compound layer 2a (green organic compound layer) in which the hole transport layer 12, the first emission layer 13a, the hole blocking layer 19, and the electron transport layer 14 are laminated in this order was formed.

(Step of Processing First Organic Compound Layer)

Next, a polyvinylpyrrolidone (PVP) layer and a silicon nitride layer were formed in this order on the first organic compound layer 2a. It should be noted that the polyvinylpyrrolidone (PVP) layer functions as a first intermediate layer 21, and the silicon nitride layer functions as a second intermediate layer 22.

Next, the two intermediate layers were processed so that the first intermediate layer 21 and the second intermediate layer 22 remain only on a first sub-pixel (green sub-pixel) by patterning using photolithography. Hereinafter, a specific process of the step of processing the intermediate layers is described.

First, the second intermediate layer 22 was coated with hexamethyldisilazane (HMDS), and then coated with a positive photoresist AZ1500 produced by AZ Electronic Materials through use of a spin coater. Then, if required, the positive photoresist was pre-baked to form a resist layer 23 having a thickness of 1 μm. It should be noted that, in a light shielding portion of a photomask used in the exposing step to be performed next, a chromium layer having a thickness of about 200 nm of a size of 31.5 μm×94.5 μm was provided in a pattern shape, and a total of light transmittances of the light shielding portion and the resist layer 23 formed of a positive resist was very small, i.e., the total light transmittance with respect to the absorption wavelength of the constituent material for the organic EL element and the wavelength of visible light was 1% or less. Further, the photomask was designed so as to be a size larger, compared with the size of the first electrode to be the emission region of the organic EL element. Therefore, a distance D in a planar direction between a border L₁ of a light shielding portion 31 and a non-light-shielding portion 32 of a photomask 30 and a border L₂ of an emission region A and a non-emission region B illustrated in FIG. 4 is a half or more of a resolution of 3.5 μm in photolithography. Thus, during the exposing step, the first organic compound layer 2a (green organic compound layer) is not irradiated with light from the exposure device. After the exposing step was performed, development and post-baking were performed. At this time, the resist layer 23 remained only in a region in which the green sub-pixel was provided.

Next, dry etching using carbon tetrafluoride gas (CF₄ gas) as etching gas was performed using the patterned resist layer as a mask to remove the intermediate layers (21, 22) provided in the regions other than the region in which the green sub-pixel was provided. At this time, the intermediate layers (21, 22) remained only in the region in which the green sub-pixel was provided. Next, dry etching using oxygen gas as etching gas was performed using the patterned intermediate layers (21, 22) as a mask to remove the first organic compound layer 2a provided in the region other than the sub-pixel of a first color (green sub-pixel).

(Step of Forming Second Organic Compound Layer)

Next, a second organic compound layer 2b including a hole transport layer 12, a second emission layer 13b, a hole blocking layer 19, and an electron transport layer 14 was formed at least on the lower electrode 11b by vacuum deposition. It should be noted that the second emission layer 13b contained a red emission material.

(Step of Processing Second Organic Compound Layer)

Next, the same process as that of the step of processing the first organic compound layer 2a described above was performed to remove the second organic compound layer 2b provided in the region other than the region in which the sub-pixel of a second color (red sub-pixel) was provided.

(Step of Forming Third Organic Compound Layer)

Next, a third organic compound layer 2c including a hole transport layer 12, a third emission layer 13c, a hole blocking layer 19, and an electron transport layer 14 was formed at least on the lower electrode 11c by vacuum deposition. It should be noted that the third emission layer 13c contained a blue emission material.

(Step of Processing Third Organic Compound Layer)

Next, the same process as that of the step of processing the first organic compound layer 2a described above was performed to remove the third organic compound layer 2c provided in the region other than the region in which the sub-pixel of a third color (blue sub-pixel) was provided.

(Step of Removing Intermediate Layer)

Next, the substrate 10 having the three kinds of organic compound layers (2a, 2b, 2c) formed thereon was immersed in water to remove the first intermediate layer 21 together with the second intermediate layer 22. It should be noted that PVP serving as the constituent material for the first intermediate layer 21 was water-soluble, and hence, when the substrate 10 was immersed in water, the first intermediate layer 21 was first dissolved in water and then the second intermediate layer 22 was peeled and removed from the organic compound layers (2a, 2b, 2c) due to the dissolution of the first intermediate layer 21. Next, the organic compound layers were baked at 100° C. in order to remove water adhering to the front or side surface of the organic compound layers.

(Step of Forming Common Layer)

Next, an organic material represented by the following formula and cesium carbonate were co-deposited from the vapor on the organic compound layers (2a, 2b, 2c) to form an electron injection layer 15 as a layer common to the respective sub-pixels (common layer). In this case, the thickness of the electron injection layer 15 was set to be 20 nm.

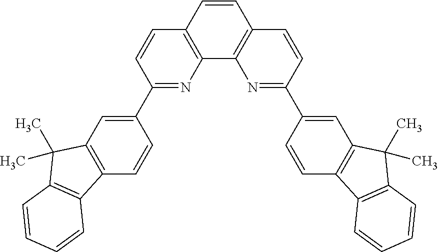

(Step of Forming Common Electrode)

Next, silver was formed into a film on the electron injection layer 15 by sputtering to form an upper electrode 16 as a common electrode. In this case, the thickness of the upper electrode 16 was set to be 10 nm.

(Sealing Step)

Finally, an organic EL display device was sealed with a cap glass in a glove box filled with nitrogen. Thus, an organic EL display device was obtained.

(Evaluation of Organic EL Display Device)

Regarding the obtained organic EL display device, the light emitting efficiency of the green sub-pixel included in the device was measured and evaluated. As a result, a graph shown in FIG. 5 was obtained.

(Surface Observation of Pixel Region)

The obtained EL display device was observed with an organic microscope, and residues were not observed in any of the pixel regions of the first organic compound layer, the second organic compound layer, and the third organic compound layer.

### Comparative Example 1

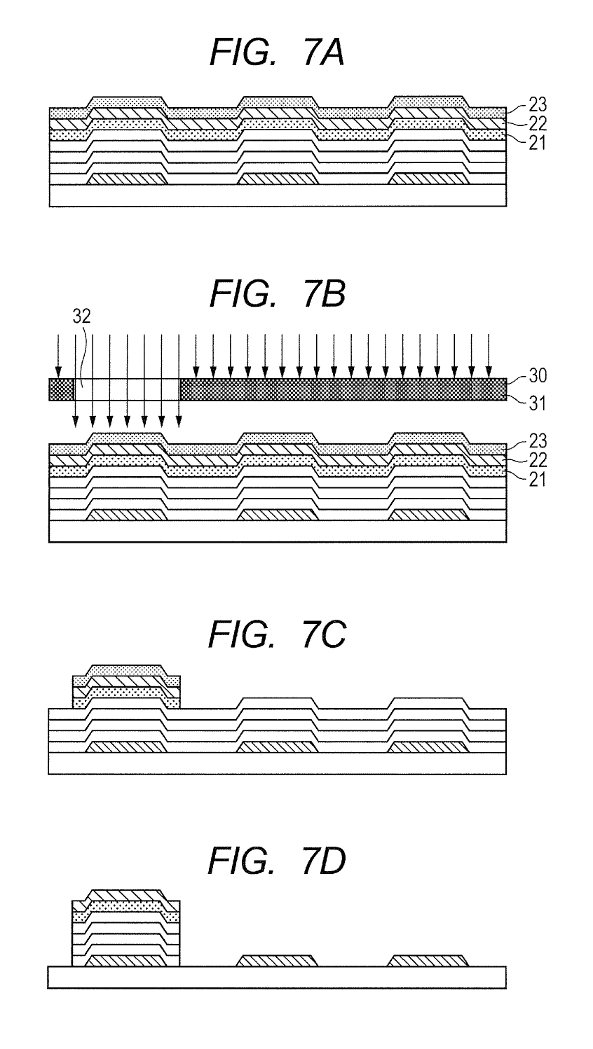

An organic EL display device was obtained by the same method as that of Example 1, except for using a negative resist instead of a positive resist, as the resist used in the step of treating the first organic compound layer. FIGS. 7A to 7D are schematic cross-sectional views illustrating the step of treating the organic compound layer in this comparative example. In the same way as in Example 1, the first organic compound layer to the resist layer 23 were formed (FIG. 7A), and the resist layer 23 was exposed to light through use of the photomask 30 having the light shielding portion 31 and the non-light-shielding portion 32 according to a pattern for removing the first organic compound layer (FIG. 7B). After that, development and post-baking were performed. In this comparative example, the negative resist was used, and hence, light was shielded by the light shielding portion 31 and the resist layer 23 in a non-exposed region was removed by development (FIG. 7C). Next, the intermediate layers (21, 22) were removed using the resist layer remaining on the surface of the second protective layer 22 as a mask, and further, the first organic compound layer 2a was removed (FIG. 7D).

Regarding the obtained organic EL display device, the light emitting efficiency of the green sub-pixel included in the device was measured and evaluated. As a result, a graph shown in FIG. 6 was obtained. That is, it was found that the organic EL display device of this comparative example was inferior to the organic EL display device of Example 1 in the light emitting efficiency as one of emission characteristics.

FIGS. 7A to 7D are schematic cross-sectional views illustrating the step of treating the organic compound layer in this comparative example. Particularly as illustrated in FIG. 7B, in the case of using the negative resist, light from the exposure device can reach the organic compound layer constituting the organic EL element in the exposing step. It was confirmed that, due to this situation, the constituent material for the organic compound layer (particularly, first emission layer) was changed (degraded) with light from the exposure device. On the other hand, when the obtained EL display device was observed with an organic microscope, residues were observed in pixel regions of the second organic compound layer and the third organic compound layer. The residues were subjected to secondary ion mass spectrometry (SIMS), and were identified as polyvinylpyrrolidone (PVP). The reason for this is considered as follows. A sub-pixel region to be removed was exposed to light because the negative resist was used, and hence, an intermediate layer material was not irradiated with ultraviolet light and was not decomposed easily to remain as residues.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-217663, filed Sep. 30, 2011, and Japanese Patent Application No. 2012-189766, filed Aug. 30, 2012 which are hereby incorporated by reference herein in their entirety.

What is claimed is:

1. A method of producing an organic electroluminescence display device including patterning an organic compound layer by photolithography, the method comprising:
forming an organic compound layer comprising a low-molecular organic electroluminescence material;
forming an intermediate layer for protecting the organic compound layer on the organic compound layer;
forming a resist layer on the intermediate layer;
irradiating the photoresist layer with ultraviolet light through a photomask having a patterned light shielding portion to partially remove the resist layer in a region irradiated with the ultraviolet light; and
removing the organic compound layer in a region from which the resist layer is removed,
wherein the resist layer comprises a layer formed of a positive resist, and
the intermediate layer comprises a layer formed of a high-molecular organic material having a chain structure, capable of being selectively dissolved in a solvent that dissolves the organic compound layer.

2. The method according to claim 1, wherein the high-molecular organic material having a chain structure comprises one of a water-soluble polymer material and an alcohol-soluble polymer material.

3. The method according to claim 2, wherein the high-molecular organic material having a chain structure comprises polyvinylpyrrolidone.

4. The method according to claim 1, wherein the intermediate layer comprises a layer in which a layer formed of an inorganic material is laminated on the layer formed of the high-molecular organic material having a chain structure.

5. The method according to claim 4, wherein the inorganic material comprises silicon nitride.

6. The method according to claim 1, wherein a total of a light transmittance of the light shielding portion of the photomask and a light transmittance of the resist layer formed of the positive resist is 1% or less with respect to the ultraviolet light.

7. The method according to claim 1, wherein a light transmittance of a member provided between lower electrodes included in the organic electroluminescence display device and owned by sub-pixels adjacent to each other is 85% or less with respect to the ultraviolet light.

8. The method according to claim 1, wherein a light transmittance of a member provided between lower electrodes included in the organic electroluminescence display device and owned by sub-pixels adjacent to each other is 15% or less with respect to the ultraviolet light.

9. The method according to claim 1, wherein a light transmittance of a transparent electrode included in the organic electroluminescence display device is 90% or less with respect to the ultraviolet light.

10. The method according to claim 1, wherein a light transmittance of a planarized passivation film included in the organic electroluminescence display device is 1% or less with respect to the ultraviolet light.
